(19) United States
(12) Patent Application Publication
(10) Pub. No.: US 2026/0293397 A1
(43) Pub. Date: Sep. 24, 2026

(54) DISPLAY DEVICE

(71) Applicant: LG Display Co., Ltd., Seoul (KR)

(72) Inventors: Hyunseok NA, Paju-si (KR); Woosung KIM, Paju-si (KR); Seongsoo CHO, Paju-si (KR); Sanghak SHIN, Paju-si (KR)

(73) Assignee: LG Display Co., Ltd., Seoul (KR)

(21) Appl. No.: 19/574,212

(22) Filed: Mar. 20, 2026

(30) Foreign Application Priority Data
Mar. 24, 2025 (KR) 10-2025-0037057

(51) Int. Cl. H10H 29/39; H10H 29/41

(52) U.S. Cl. CPC H10H 29/39; H10H 29/41

(57) ABSTRACT

A display device includes a substrate having transistors and lower connection electrodes, insulating and protective layers disposed on the substrate, and an element disposed above an adhesive layer. An upper connection electrode has a concave end portion that laterally contacts side surfaces of an element contact electrode while also electrically connecting to a lower connection electrode through the adhesive layer. A further upper electrode connects another element contact electrode to an upper routing electrode across the insulating layers. The structure forms multiple conductive paths between the element and the driving circuitry and maintains electrical coupling even when alignment variation or interface degradation occurs. The side surface engagement increases contact area, reduces contact resistance, and improves electrical stability. The arrangement enables simplified assembly and reduced power consumption in a display panel.

### CROSS-REFERENCE TO RELATED APPLICATION

The present application claims priority to Korean Patent Application No. 10-2025-0037057, filed Mar 24, 2025, the entire contents of which is incorporated herein for all purposes by this reference.

### BACKGROUND

### Technical Field

The present specification relates to a display device.

### Description of the Related Art

Liquid crystal display (LCD) displays, organic light emitting (OLED) display devices, and quantum dot display devices (QDs), which are widely used today, are gradually expanding their application scope.

The display devices implement an image by arranging a plurality of light-emitting elements on a substrate of the display device, and by arranging, on the same substrate, driving elements for supplying driving signals or driving current to control each light-emitting element to emit light individually, and thus the plurality of light-emitting elements disposed on the substrate are driven according to the arrangement of information to be displayed so that the information is displayed on the substrate.

The LCD is not self-luminous and thus requires a backlight unit disposed to emit light from a rear surface of the LCD. The backlight unit can increase the thickness of the LCD, limit the implementation of various display shapes, such as flexible, circular, and the like, and reduce luminance and response time.

Meanwhile, display devices with self-luminous elements can be thinner than display devices with built-in light sources, enabling flexible and foldable display devices. The display devices with the self-luminous elements may include OLEDs containing organic materials as a light-emitting layer, light-emitting diode (LED) display devices using LEDs as the light-emitting elements, and the like, and the self-luminous displays, such as an OLED display device or an LED display device, do not require a separate light source, allowing for thinner displays and a wider range of display formats.

However, since the OLED display device using organic materials are prone to defective pixels, such as oxidation between an organic light-emitting layer and electrodes due to moisture and oxygen penetration, various technical configurations are required to minimize such penetration.

Recently, research and development on display devices using inorganic LEDs as light-emitting elements is underway, and these light-emitting display devices are attracting attention as next-generation displays due to high image quality and high reliability.

### BRIEF SUMMARY

The present disclosure describes a display pixel interconnection structure in which an upper connection electrode has a concave terminal portion that laterally engages side surfaces of an element contact electrode through an adhesive layer. In contrast to planar pad bonding or bump based vertical contacts, the geometry mechanically retains the electrode during assembly and forms an enlarged sidewall contact area. This arrangement provides self alignment, lowers contact resistance, and reduces open circuit failure caused by shrinkage, misalignment, or thermal stress.

The electrode network further routes conductive paths through multilayer insulating and protective stacks so that a connection electrode penetrates the adhesive and simultaneously couples lower electrodes and the device electrode. Multiple parallel current paths are therefore formed, allowing continued operation even if one interface degrades. The concave capture shape also functions as a stress relief structure that stabilizes the joint without relying on conductive particles or solder bumps.

Overall, the structure provides a reliability oriented display interconnect architecture that replaces precision bonding with a geometrically self securing electrode interface. By combining sidewall electrical contact, redundant conductive routing, and integrated multilayer vias, the arrangement simplifies fabrication while reducing resistance and power consumption and preventing pixel disconnection.

For example, embodiments of the present specification are directed to providing a display device capable of stable connection between a first element contact electrode and a third upper connection electrode.

Embodiments of the present specification are also directed to providing a display device with a simplified process.

Embodiments of the present specification are also directed to providing a display device capable of preventing disconnection of a fourth upper connection electrode.

Embodiments of the present specification are also directed to providing a display device driven at low power.

Objects of the present specification are not limited to the above objects, and other technical objects may be inferred from the following embodiments.

According to one embodiment, there is provided a display device including a substrate, a transistor on the substrate, a first protective layer on the transistor, a second protective layer on the first protective layer, a first lower connection electrode connected to the transistor through the first protective layer and the second protective layer, a second lower connection electrode disposed on the second protective layer and spaced apart from the first lower connection electrode, a lower insulating layer on the first lower connection electrode and the second lower connection electrode, a first upper connection electrode connected to the first lower connection electrode through the lower insulating layer on the lower insulating layer, a second upper connection electrode connected to the second lower connection electrode through the lower insulating layer on the lower insulating layer, an adhesive layer on the first upper connection electrode and the second upper connection electrode, a first element contact electrode on the adhesive layer, a light-emitting element on the first element contact electrode, a second element contact electrode on the light-emitting element, a third upper connection electrode connected to the second lower connection electrode through the adhesive layer and connected to side surfaces of the first element contact electrode, a first upper insulating layer on the adhesive layer and the third upper connection electrode, a second upper insulating layer on the first upper insulating layer, and a fourth upper connection electrode disposed on the second upper insulating layer and the second element contact electrode, connected to the first upper connection electrode through the second upper insulating layer, the first upper insulating layer, and the adhesive layer, and connected to the second element contact electrode, in which an end portion of the third upper connection electrode connected to side surfaces of the first element contact electrode is concave.

According to another embodiment of the present specification, there is provided a display device including a substrate, a driver adhesive layer on the substrate, a driving driver on the driver adhesive layer, a first protective layer on the driving driver, a second protective layer on the first protective layer, a first lower connection electrode disposed on the second protective layer and connected to a transistor through the first protective layer and the second protective layer, a second lower connection electrode disposed on the second protective layer and spaced apart from the first lower connection electrode, a lower insulating layer on the first lower connection electrode and the second lower connection electrode, a first upper connection electrode connected to the first lower connection electrode through the lower insulating layer on the lower insulating layer, a second upper connection electrode connected to the second lower connection electrode through the lower insulating layer on the lower insulating layer, an adhesive layer on the first upper connection electrode and the second upper connection electrode, a first element contact electrode on the adhesive layer, a light-emitting element on the first element contact electrode, a second element contact electrode on the light-emitting element, a third upper connection electrode connected to the second lower connection electrode and side surfaces of the first element contact electrode through the first adhesive layer, a first upper insulating layer on the adhesive layer and the third upper connection electrode, a second upper insulating layer on the first upper insulating layer, and a fourth upper connection electrode disposed on the second upper insulating layer and the second element contact electrode, connected to the first upper connection electrode through the second upper insulating layer, the first upper insulating layer, and the adhesive layer, and connected to the second element contact electrode, in which an end portion of the third upper connection electrode connected to side surfaces of the first element contact electrode is concave.

Detailed matters of other embodiments are included in the detailed description and accompanying drawings.

### BRIEF DESCRIPTION OF THE SEVERAL VIEWS OF THE DRAWINGS

FIG. 1 is a cross-sectional view of a display device according to one embodiment.

FIG. 2 is a schematic plan view of the display device according to one embodiment.

FIGS. 3-8 are cross-sectional views for each process illustrating a method of manufacturing the display device according to one embodiment.

FIG. 9 is a cross-sectional view of a display device according to another embodiment.

FIG. 10 is a cross-sectional view of a display device according to still another embodiment.

### DETAILED DESCRIPTION

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the specification, when a certain component (or an area, a layer, a portion, etc.) is described as “on,” “connected,” or “coupled to” another component, it means that the certain component may be directly connected/coupled to another component or still another component may be disposed therebetween.

The term “and/or” includes all one or more combinations that may be defined by the associated configurations.

Terms such as “first,” “second,” and the like may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc., can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various embodiments of the present specification may be coupled or combined partially or entirely, various technological interworking and driving are made possible, and the embodiments may be implemented independently of each other or implemented together in an associated relationship.

Hereinafter, a display device of the present specification will be described with reference to the accompanying drawings and embodiments as follows.

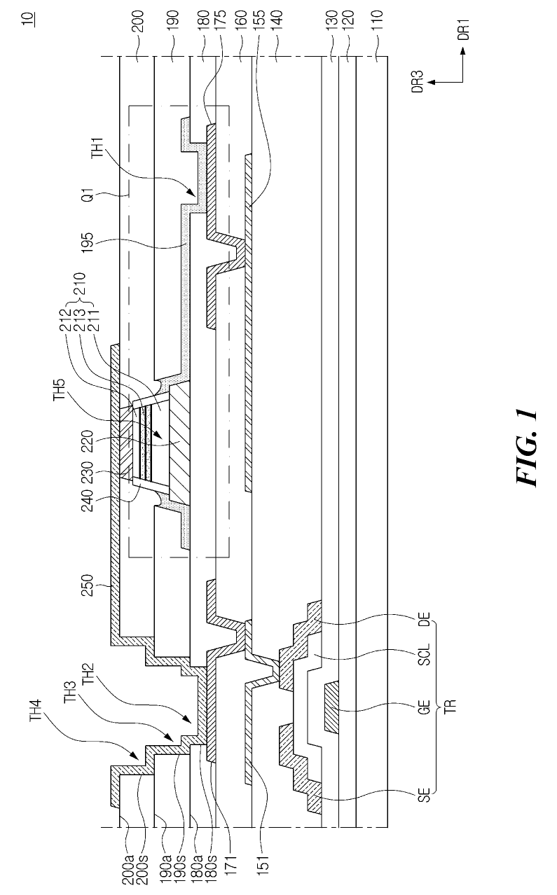

FIG. 1 is a plan view of a display device according to one embodiment.

Referring to FIG. 1, a display device 10 according to one embodiment may include a substrate 110, a buffer layer 120, at least one transistor TR, a gate insulating layer 130, a first protective layer 140, lower connection electrodes 151 and 155, a second protective layer 160, upper connection electrodes 171, 175, 195, and 250, an adhesive layer 180, upper insulating layers 190 and 200, a light-emitting element 210, contact electrodes 220 and 230, and a side insulating layer 240.

The substrate 110 is an array substrate on which transistors are formed and includes a plastic material or a glass material.

The substrate 110 according to one embodiment may include an opaque or colored polyimide material. In this case, the display device 10 may further include a back plate coupled to a rear surface of the substrate 110 to maintain the substrate 110 in a flat surface state. In one embodiment, the back plate may include a plastic material, for example, a polyethylene terephthalate material. In some embodiments, the substrate 110 may be a glass substrate. For example, the glass substrate 110 may be a thin glass substrate having a thickness of 100 μm or less and may have flexible properties. In some embodiments, the substrate 110 may be formed by bonding two or more substrates or being divided into two or more layers.

The buffer layer 120 may be disposed on the substrate 110. The buffer layer 120 can minimize or delay the diffusion of moisture or oxygen penetrating the substrate 101. The buffer layer 120 may be formed by alternately stacking silicon nitride (SiNₓ) and silicon oxide (SiOₓ) at least once, but the embodiments of the present specification are not limited thereto.

The transistor TR may be disposed on the buffer layer 120. The transistor TR may include a gate electrode GE, a semiconductor layer SCL, a source electrode SE, and a drain electrode DE. The gate electrode GE may be formed of a semiconductor, such as silicon (Si) or the like, a conductive metal, for example, molybdenum (Mo), aluminum (Al), chromium (Cr), gold (Au), titanium (Ti), nickel (Ni), neodymium (Nd), and copper (Cu), an alloy of two or more thereof, or multiple layers thereof.

The gate insulating layer 130 may be disposed on the gate electrode GE. The gate insulating layer 130 may be formed of a single layer or multiple layers of inorganic materials, such as silicon oxide (SiOₓ), silicon nitride (SiNₓ), etc. The gate insulating layer 130 may insulate the gate electrode GE from the semiconductor layer SCL.

The semiconductor layer SCL may be disposed on the gate insulating layer 130. The semiconductor layer SCL is formed in a predetermined pattern on the gate insulating layer 130 so as to overlap the gate electrode GE. The semiconductor layer SCL may be formed of a semiconductor material including any one of amorphous silicon, polycrystalline silicon, oxide, and organic materials, but the embodiments of the present specification are not limited thereto.

The source electrode SE and the drain electrode DE may be disposed on the semiconductor layer SCL. The source electrode SE may be disposed to overlap the other side of the semiconductor layer SCL in a first direction DR1, and the drain electrode DE may be disposed to overlap one side of the semiconductor layer SCL in the first direction DR1.

In the present specification, the gate electrode GE is exemplified as being disposed below the semiconductor layer SCL, but is not limited thereto, and the gate electrode GE may be disposed on the semiconductor layer SCL, and the source electrode SE and drain electrode DE may each be connected to the semiconductor layer SCL through the gate insulating layer. The source electrode SE and drain electrode DE may be a semiconductor, such as silicon (Si) or the like, or a conductive metal, for example, one of molybdenum (Mo), aluminum (Al), chromium (Cr), gold (Au), titanium (Ti), nickel (Ni), neodymium (Nd), and copper (Cu), an alloy of two or more thereof, or multiple layers thereof.

The first protective layer 140 may be disposed on the source electrode SE and the drain electrode DE. The first protective layer 140 may protect the underlying transistor TR while providing a flat surface. According to one embodiment, the first protective layer 140 may be formed of an organic material such as benzocyclobutene or photo acryl, but the embodiments of the present specification are not limited thereto.

The lower connection electrodes 151 and 155 may be disposed on the first protective layer 140. The lower connection electrodes 151 and 155 may be formed of any one of molybdenum (Mo), aluminum (Al), chromium (Cr), gold (Au), titanium (Ti), nickel (Ni), neodymium (Nd), and copper (Cu), an alloy of two or more thereof, or multiple layers thereof. The first lower connection electrode 151 may be electrically connected to the drain electrode DE through the first protective layer 140. The second lower connection electrode 155 may be spaced apart from the first lower connection electrode 151 and disposed on the same layer. A common voltage (or a cathode voltage) may be applied to the second lower connection electrode 155, but the embodiments of the present specification are not limited thereto.

The second protective layer 160 may be disposed on the lower connection electrodes 151 and 155. A material of the second protective layer 160 may be one of the above examples of the first protective layer 140, but the embodiments of the present specification are not limited thereto.

The first and second upper connection electrodes 171 and 175 may be disposed on the second protective layer 160. The first and second upper connection electrodes 171 and 175 may include the same material and may be disposed on the same layer. The first and second upper connection electrodes 171 and 175 may be formed of at least one of molybdenum (Mo), aluminum (Al), chromium (Cr), gold (Au), titanium (Ti), nickel (Ni), neodymium (Nd), and copper (Cu), an alloy of two or more thereof, or multiple layers thereof. The first upper connection electrode 171 may be electrically connected to the first lower connection electrode 151 through the second protective layer 160, and the second upper connection electrode 175 may be electrically connected to the second lower connection electrode 155 through the second protective layer 160.

The adhesive layer 180 may be disposed on the first and second upper connection electrodes 171 and 175. The adhesive layer 180 can minimize movements of the element contact electrodes 220 and 230 and the light-emitting element 210 disposed on the adhesive layer 180.

The element contact electrodes 220 and 230 and the light-emitting element 210 may be disposed on the adhesive layer 180. The light-emitting element 210 may include a first electrode 211, a second electrode 212 facing the first electrode 211, and an active layer 213 between the first electrode 211 and the second electrode 212.

A first element contact electrode 220 may be disposed directly on the adhesive layer 180. The first element contact electrode 220 may include a light-reflection conductive material. The light-reflection conductive material may be Al, Ag, Au, Pt, or Cu, but is not limited thereto.

The second element contact electrode 230 may include a transparent conductive material. The transparent conductive material may be, for example, indium tin oxide (ITO), indium zinc oxide (IZO), or the like, but the embodiments of the present specification are not limited thereto.

In the present specification, a top-emitting method has been described as an example, but the embodiments of the present specification are not limited thereto and a bottom-emitting method may also be provided. In this case, materials of the first and second element contact electrodes 220 and 230 may be interchangeable.

The first electrode 211 of the light-emitting element 210 may be an n-type electrode and a cathode terminal, and the second electrode 212 may be a p-type electrode and an anode terminal, but the embodiments of the present specification are not limited thereto, and this case may be reversed. The recombination of electrons and holes occurs in the active layer 213 according to the current flowing between the first electrode 151 and the second electrode 153, thereby enabling the active layer 213 to emit light. The first element contact electrode 220 may be connected to the first electrode 211, and the second element contact electrode 230 may be connected to the second electrode 212.

The element insulating layer 240 may be disposed on side surfaces of the light-emitting device 210. The element insulating layer 240 may be disposed on both side surfaces of the light-emitting element 210 and can prevent the light-emitting element 210 from being connected to an adjacent electrode (e.g., a third upper connection electrode 195). The element insulating layer 240 may include an inorganic material.

The light-emitting element 210 may be disposed on a central portion of the first element contact electrode 220 and may expose an outer portion of the first element contact electrode 220. In the present specification, the central portion of the first element contact electrode 220 is a central portion of an upper surface of the first element contact electrode 220, and the outer portion thereof may be an area of the upper surface of the first element contact electrode 220 excluding the central portion. The element insulating layer 240 may be disposed on an upper surface of the outer portion of the first element contact electrode 220 exposed by the light-emitting element 210.

The third upper connection electrode 195 on the adhesive layer 180 may be electrically connected to the second upper connection electrode 175 through the adhesive layer 180 (see a first through hole TH1). The third upper connection electrode 195 may be electrically connected to the first element contact electrode 220. The third upper connection electrode 195 may be in contact with side surfaces of the first element contact electrode 220 (side contact) and may also be in contact with the upper surface of the outer portion of the first element contact electrode 220 exposed by the light-emitting element 210 and the element insulating layer 240. An end portion of the third upper connection electrode 195 disposed between the element insulating layer 240 and the first upper insulating layer 190 may have a curved shape. The end portion of the third upper connection electrode 195 may be disposed between the element insulating layer 240 and the first upper insulating layer 190 or between the light-emitting element 210 and the first upper insulating layer 190. The curved shape of the end portion of the electrode 195 may be an inward recessed shape (or a concave shape) (also may be referred to as ‘the recessed end portion’). The curved shape of the end portion of the third upper connection electrode 195 is due to the application of a wet etching process as will be described below. The description thereof will be provided in detail below.

The third upper connection electrode 195 may cover only the lower end portion of the element insulating layer 240 and expose an upper end portion of the element insulating layer 240, and the third upper connection electrode 195 may be spaced apart from the second element contact layer 230.

However, the embodiments of the present specification are not limited thereto, and the third upper connection electrode 195 may also cover an upper portion of the element insulating layer 240. However, even in this case, the third upper connection electrode 195 needs to be spaced apart from the second element contact layer 230.

In some embodiments, the third upper connection electrode 195 may not be in contact with the element insulating layer 240. That is, the third upper connection electrode 195 may be in contact with only the side surfaces of the first element contact layer 220 and may not be in contact with the element insulating layer 240.

In the case of a vertical light-emitting element as in the present embodiment, electrical connection with the electrodes formed on the panel is required simultaneously with the transfer of the element, and thus an eutectic bonding or anisotropic conductive film (ACF) method may be used. However, since the eutectic bonding method requires a high-temperature process of 300 °C or higher, alignment between the element and the electrodes may be difficult due to temperature fluctuations. Likewise, since the ACF method also requires a high-temperature and high-pressure process, the alignment between the element and the electrodes may be difficult.

However, according to the display device 10 according to one embodiment, the first element contact electrode 220 and the third upper connection electrode 195 form side contact, thereby enabling stable connection between the light-emitting element and the electrodes.

The third upper connection electrode 195 may be disposed to surround the light-emitting element 210.

The third upper connection electrode 195 may be spaced apart from the second element contact electrode 230 and electrically isolated therefrom.

The first upper insulating layer 190 may be disposed on the third upper connection electrode 195. The first upper insulating layer 190 may include an organic or inorganic material. The first upper insulating layer 190 may mask the remaining area of the third upper connection electrode excluding the area disposed on the underlying second element contact electrode 230 during the wet etching process of the third upper connection electrode 195, which will be described below.

The second upper insulating layer 200 may be disposed on the first upper insulating layer 190. The second upper insulating layer 200 may include an organic or inorganic material. The second upper insulating layer 200 can prevent the third upper connection electrode 195 and a fourth upper connection electrode 250 from being electrically connected.

The fourth upper connection electrode 250 may be disposed on the second upper insulating layer 200. The fourth upper connection electrode 250 may be electrically connected to the first upper connection electrode 171 through a fourth through hole TH4 of the second upper insulating layer 200, a third through hole TH3 of the first upper insulating layer 190, and a second through hole TH2 of the adhesive layer 180. The second through hole TH2, the third through hole TH3, and the fourth through hole TH4 may overlap each other in the thickness direction. A width of the fourth through hole TH4 may be larger than a width of the third through hole TH3, and the width of the third through hole TH3 may be larger than a width of the second through hole TH2. That is, the second upper insulating layer 200, the first upper insulating layer 190, and the adhesive layer 180 may have a step structure as illustrated in FIG. 1. According to the embodiments of the present specification, the second upper insulating layer 200, the first upper insulating layer 190, and the adhesive layer 180 may have a step structure as illustrated in FIG. 1, thereby preventing disconnection of the fourth upper connection electrode 250 disposed thereon. The fourth upper connection electrode 250 may be in contact with an upper surface of the second upper insulating layer 200, may be in contact with an upper surface of the second element contact electrode 230, and may be electrically connected to the second element contact electrode 230. As an example, FIG. 1 illustrates a corner at which an upper surface 180a and side surfaces 180s of the adhesive layer 180 meet being a right angle, a corner at which an upper surface 190a and side surfaces 190s of the first upper insulating layer 190 meet being a right angle, and a corner at which an upper surface 200a and a side surface 200s of the second upper insulating layer 200 meet being a right angle.

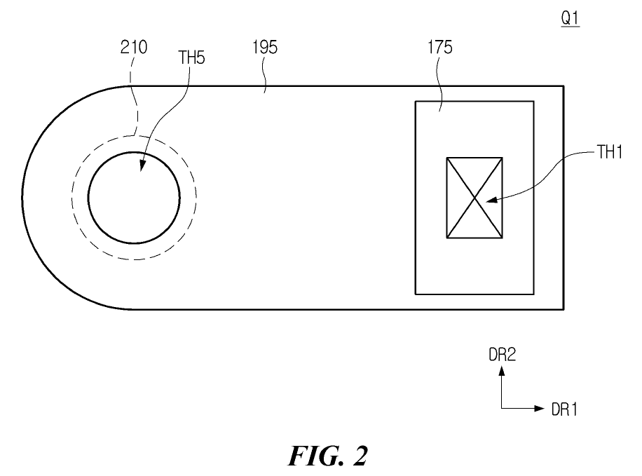

FIG. 2 is a schematic plan view of the display device according to one embodiment. FIG. 2 illustrates a schematic plan view of the light-emitting element 210, the third upper connection electrode 195, and the second upper connection electrode 175 that are positioned in area Q1 in FIG. 1.

Referring to FIG. 2, as described in FIG. 1, the third upper connection electrode 195 may be disposed to surround the light-emitting element 210. In the fifth through hole TH5, the third upper connection electrode 195 may be electrically isolated from the second element contact layer 230. In the first through hole TH1, the third upper connection electrode 195 may be connected to the second upper connection electrode 175.

Hereinafter, a method of manufacturing the display device 10 according to one embodiment will be described.

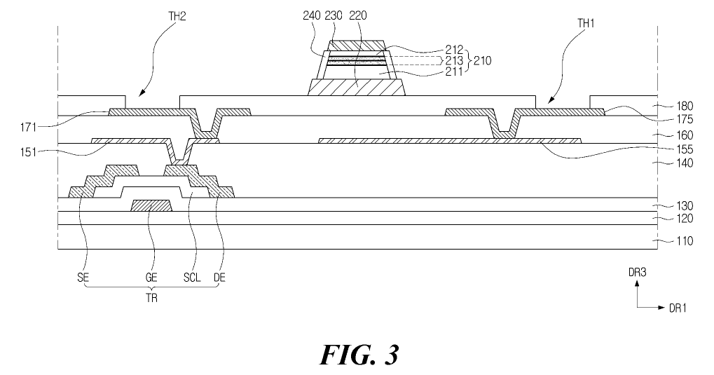

FIGS. 3-8 are cross-sectional views for each process illustrating a method of manufacturing the display device according to one embodiment.

Referring to FIGS. 1 and 3, a method of manufacturing a display device according to one embodiment may form the through holes TH1 and TH2, which passes through the first upper insulating layer 180, in the first upper insulating layer 180. In the first and second through holes TH1 and TH2, the upper surfaces of the second upper connection electrode 175 and the first upper connection electrode 171 may be exposed.

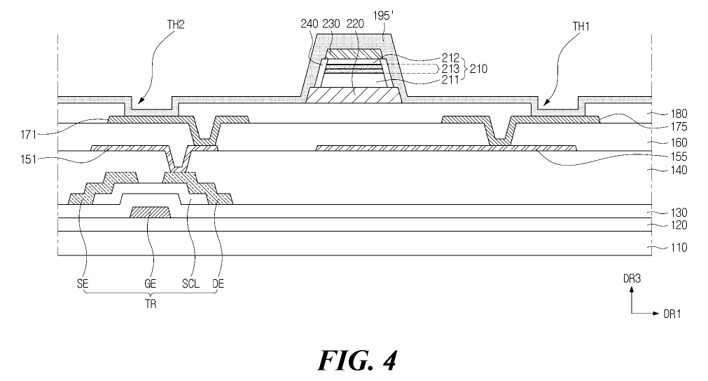

Subsequently, referring to FIGS. 1 and 4, a method of manufacturing a display device according to one embodiment may form a third upper connection electrode 195′. The third upper connection electrode 195′ may be disposed over the entire surfaces of the adhesive layer 180, the first upper connection electrode 171, the second upper connection electrode 175, the first element contact electrode 220, the light-emitting element 210, and the second element contact electrode 230.

The third upper connection electrode 195′ may be in direct contact with the adhesive layer 180, the first upper connection electrode 171, the second upper connection electrode 175, the first element contact electrode 220, and the second element contact electrode 230.

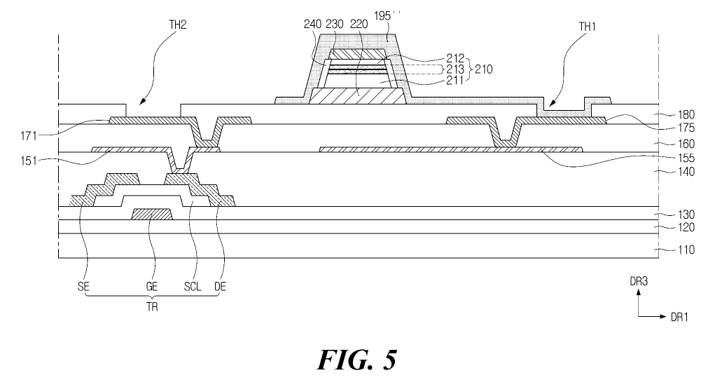

Subsequently, referring to FIGS. 1 and 5, a third upper connection electrode 195″ is formed. The third upper connection electrode 195″ may be formed by removing an area of the third upper connection electrode 195′ of FIG. 4 that overlaps the second through hole TH2. That is, the third upper connection electrode 195″ may not overlap the second through hole TH2. The third upper connection electrode 195″ may not overlap the first upper connection electrode 171, but the embodiments of the present specification are not limited thereto.

An operation of forming the third upper connection electrode 195″ may be performed through etching. For example, based on FIG. 4, a photoresist may be disposed in an area excluding the third upper connection electrode 195″ of FIG. 5, and etching may be performed using the photoresist as a mask. The etching may be dry etching or wet etching.

Accordingly, although not illustrated, the surface roughness of the first upper connection electrode 171 in the second through hole TH2 may be greater than the surface roughness of the first upper connection electrode 171 that does not overlap the second through hole TH2.

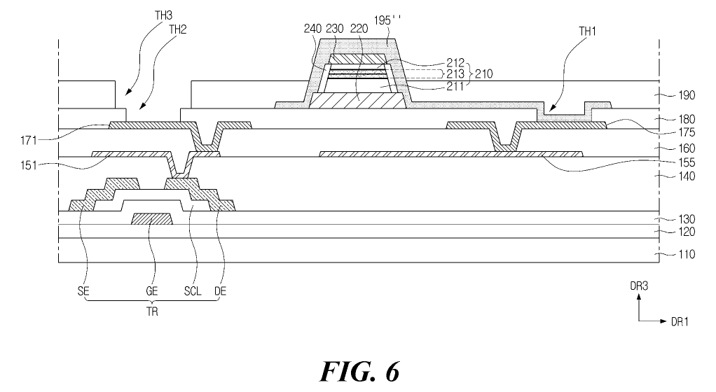

Subsequently, referring to FIGS. 1 and 6, the first upper insulating layer 190 is formed. The first upper insulating layer 190 may have the third through hole TH3. The first upper insulating layer 190 may expose an area overlapping the second through hole TH2 and the third upper connection electrode 195″ positioned on the side and upper surfaces of the light-emitting element 210. That is, the first upper insulating layer 190 may expose an upper portion of the third upper connection electrode 195″ disposed on the side surfaces of the light-emitting element 210 and an upper surface of the third upper connection electrode 195″ disposed on the upper surface of the light-emitting element 210. An operation of forming the first upper insulating layer 190 may also be performed through an etching process using a photoresist as a mask.

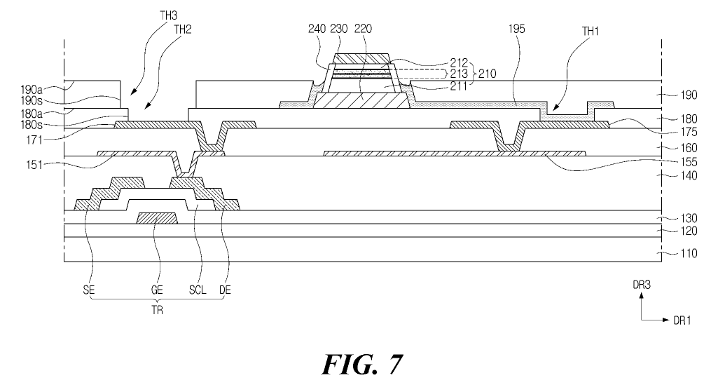

Subsequently, referring to FIGS. 1 and 7, the third upper connection electrode 195 is formed. The third upper connection electrode 195 may be formed by wet-etching the third upper connection electrode 195″ of FIG. 6. Since the third upper connection electrode 195 is formed by wet etching, an end portion of the third upper connection electrode 195 that is in contact with the first element contact electrode 220 may have a curved shape. The curved shape of the end portion of the electrode 195 may be an inward recessed shape (or a concave shape).

In addition, since the third upper connection electrode 195 is in contact with the side surfaces of the first element contact electrode 220 (side contact) and the third upper connection electrode 195 is etched to surround the light-emitting element 210, the third upper connection electrode 195 may cover only the lower end portion of the element insulating layer 240 and expose the upper portion of the element insulating layer 240, and the third upper connection electrode 195 may be spaced apart from the second device contact layer 230.

However, the embodiments of the present specification are not limited thereto, and the third upper connection electrode 195 may also cover an upper portion of the element insulating layer 240. However, even in this case, the third upper connection electrode 195 needs to be spaced apart from the second element contact layer 230.

In some embodiments, the third upper connection electrode 195 may not be in contact with the element insulating layer 240. That is, the third upper connection electrode 195 may be in contact with only the side surfaces of the first element contact layer 220 and may not be in contact with the element insulating layer 240.

Meanwhile, during the process of wet-etching the third upper connection electrode 195, the first upper connection electrode 171 may be exposed by the second and third through-holes TH2 and TH3. According to the present specification, a mask may not be applied during the process of wet-etching the third upper connection electrode 195. That is, an etching ratio of the third upper connection electrode 195 to an etchant may be significantly greater than an etching ratio of the first upper connection electrode 171 to the same etchant. For example, the etching ratio of the third upper connection electrode 195 to the etchant may be about 10 times greater than the etching ratio of the first upper connection electrode 171 to the same etchant, but the embodiments of the present specification are not limited thereto.

According to the embodiments of the present specification, since a mask is not used during the process of wet-etching the third upper connection electrode 195, the process can be simplified.

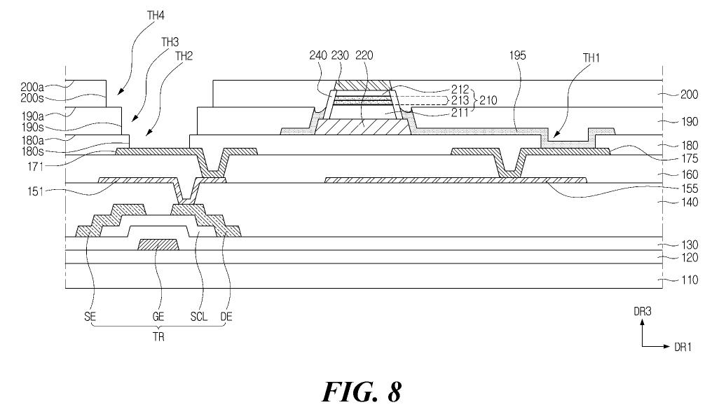

Subsequently, referring to FIGS. 1 and 8, the second upper insulating layer 200 is formed. The second upper insulating layer 200 may have the third through hole TH3.

Hereinafter, a method of manufacturing a display device according to other embodiments will be described.

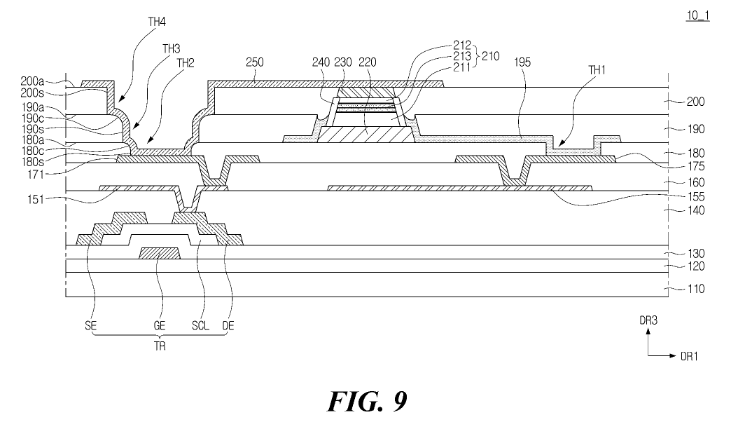

FIG. 9 is a cross-sectional view of a display device according to another embodiment.

Referring to FIG. 9, a display device 10_1 according to the present embodiment differs from the display device according to FIG. 1 in that the corners 180c of the adhesive layer 180 and the corners 190c of the first upper insulating layer 190 are rounded.

More specifically, as described above with reference to FIG. 7, during the process of forming the third upper connection electrode 195, the upper surface 190a and the side surfaces 190s of the first upper insulating layer 190 and the upper surface 180a and the side surfaces 180s of the adhesive layer 180 exposed by the first upper insulating layer 190 may be exposed to an etchant.

Accordingly, in the present embodiment, the corners 190c of the first upper insulating layer 190 and the corners 180c of the adhesive layer 180 may be formed to have curved surfaces.

Accordingly, it is possible to prevent disconnection of the fourth upper connection electrode 250.

In some embodiments, a radius of curvature of the corner 190c of the first upper insulating layer 190 may be greater than a radius of curvature of the corner 180c of the adhesive layer 180. This is because the first upper insulating layer 190 is exposed to the etchant before the adhesive layer 180.

Since the remaining parts have been described above in FIG. 1, the detailed descriptions thereof will be omitted.

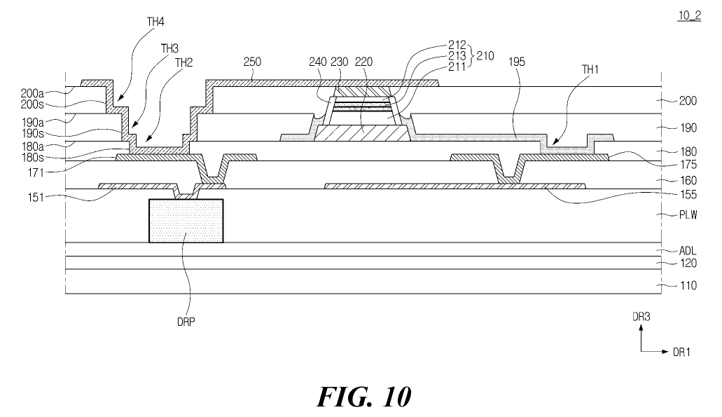

FIG. 10 is a cross-sectional view of a display device according to still another embodiment.

Referring to FIG. 10, a display device 10_2 according to the present embodiment differs from the display device 10 according to FIG. 1 in that a driving driver DRP is disposed instead of the transistor TR.

More specifically, a driver adhesive layer ADL may be disposed on the buffer layer 120, and the driving driver DRP may be disposed on the adhesive layer ADL. The adhesive layer ADL can prevent movement by bonding the driving driver DRP.

The driving driver DRP may be electrically connected to the first lower connection electrode 151.

A planarization layer PLW may be disposed on the driving driver DRP. The planarization layer PLW may planarize the step caused by the driving driver DRP. FIG. 10 illustrates the planarization layer PLW covering an outer portion of an upper surface of the driving driver DRP and exposing a central portion thereof, but the embodiments of the present specification are not limited thereto, and the planarization layer PLW may not be in contact with the upper surface of the driving driver DRP.

Even in the case of the display device 10_2 according to the embodiment of FIG. 10, the structure described above in FIG. 9 (a structure in which the corners of the first upper insulating layer 190 and the adhesive layer 180 have the curved surface) may be applied.

Since the remaining parts have been described above in FIG. 1, the detailed descriptions thereof will be omitted.

A display device according to various embodiments of the present specification may be described as follows.

As shown in FIG. 3, a display device includes a substrate 110 including a transistor TR formed thereon. A first lower connection electrode 151 is electrically connected to the transistor TR, and a second lower connection electrode 155 is laterally spaced apart from the first lower connection electrode 151 on the substrate 110. A first insulating layer (e.g., second protective layer 160) is disposed on the substrate 110, and an adhesive layer 180 is disposed on the first insulating layer. A light emitting element 210 is disposed on the adhesive layer 180, the light emitting element 210 including at least one element contact electrode 220, 230. A first upper connection electrode 171 is electrically connected to the first lower connection electrode 151, and a second upper connection electrode 175 is electrically connected to the second lower connection electrode 155.

As shown in FIG. 1, a second insulating layer (e.g., a first upper insulating layer 190) is disposed on the adhesive layer 180. A third upper connection electrode 195 extends through the adhesive layer 180 to electrically connect to the second upper connection electrode 175 and extends through the second insulating layer 190 to electrically connect to a side surface of the at least one element contact electrode. As illustrated in FIG. 1, an end portion of the third upper connection electrode 195 adjacent to the side surface of the at least one element contact electrode has an inwardly recessed shape.

As shown in FIG. 1, the at least one element contact electrode may include a first element contact electrode 220 and a second element contact electrode 230 disposed on the light emitting element 210. The third upper connection electrode 195 laterally contacts the side surface of the first element contact electrode while remaining spaced from the second element contact electrode. The lateral contact occurs along the side surface rather than a bottom surface, as depicted in the cross sectional configuration of FIG. 1.

The adhesive layer 180 includes a through hole TH1 exposing the second upper connection electrode 175. The third upper connection electrode 195 extends through the through hole TH1 in the adhesive layer 180 to contact the second upper connection electrode 175. The through hole TH1 provides an electrical path between the third upper connection electrode 195 and the second upper connection electrode 175.

As illustrated in the plan view of FIG. 2, the third upper connection electrode 195 is disposed to surround the light emitting element 210. The third upper connection electrode 195 may extend around the perimeter of the light emitting element 210 so as to contact a side surface of the element contact electrode at multiple locations.

As shown in FIG. 8, a plurality of through holes TH2, TH3, TH4 are formed through the adhesive layer 180 and the second insulating layer 190. The plurality of through holes have progressively increasing widths to form a step structure. The step structure defines a tiered opening extending toward the light emitting element 210.

As illustrated in FIGS. 9 and 10, a fourth upper connection electrode 250 is disposed on the step structure and electrically connected to the light emitting element 210. The fourth upper connection electrode 250 conforms to the stepped profile defined by the adhesive layer 180 and the second insulating layer 190.

As shown in FIG. 9, at least one corner of the adhesive layer 180 or the second insulating layer 190 is rounded or curved in an area where the fourth upper connection electrode 250 is disposed. The rounded or curved corner provides a continuous transition surface along the step structure.

As illustrated in FIG. 9, the rounded or curved corner provides a continuous surface for the fourth upper connection electrode 250 and reduces breakage during the manufacturing process by avoiding sharp edge discontinuities along the fourth upper connection electrode 250.

A display device according to various embodiments of the present specification may be further described as follows.

According to embodiments of the present specification, there is provided a display device including a substrate, a transistor on the substrate, a first protective layer on the transistor, a second protective layer on the first protective layer, a first lower connection electrode connected to the transistor through the first protective layer and the second protective layer, a second lower connection electrode disposed on the second protective layer and spaced apart from the first lower connection electrode, a lower insulating layer on the first lower connection electrode and the second lower connection electrode, a first upper connection electrode connected to the first lower connection electrode through the lower insulating layer on the lower insulating layer, a second upper connection electrode connected to the second lower connection electrode through the lower insulating layer on the lower insulating layer, an adhesive layer on the first upper connection electrode and the second upper connection electrode, a first element contact electrode on the adhesive layer, a light-emitting element on the first element contact electrode, a second element contact electrode on the light-emitting element, a third upper connection electrode connected to the second lower connection electrode through the adhesive layer and connected to side surfaces of the first element contact electrode, a first upper insulating layer on the adhesive layer and the third upper connection electrode, a second upper insulating layer on the first upper insulating layer, and a fourth upper connection electrode disposed on the second upper insulating layer and the second element contact electrode, connected to the first upper connection electrode through the second upper insulating layer, the first upper insulating layer, and the adhesive layer, and connected to the second element contact electrode, in which an end portion of the third upper connection electrode connected to side surfaces of the first element contact electrode is concave.

In the display device according to embodiments of the present specification, the third upper connection electrode may be spaced apart from the second element contact electrode.

In the display device according to embodiments of the present specification, the third upper connection electrode may surround the light-emitting element in a plan view.

In the display device according to embodiments of the present specification, the display device may further include an element insulating layer disposed on side surfaces of the light-emitting element, and the third upper connection electrode may be in direct contact with the element insulating layer.

In the display device according to embodiments of the present specification, the adhesive layer may include a second through hole exposing the first upper connection electrode, the first upper insulating layer may include a third through hole exposing the first upper connection electrode, the second upper insulating layer may include a fourth through hole exposing the first upper connection electrode, a width of the second through hole may be smaller than a width of the third through hole, and the width of the third through hole may be smaller than a width of the fourth through hole.

In the display device according to embodiments of the present specification, in an area in which the adhesive layer, the first upper insulating layer, and the second upper insulating layer expose the first upper connection electrode, the adhesive layer, the first upper insulating layer, and the second upper insulating layer may have a step structure.

In the display device according to embodiments of the present specification, in an area in which the adhesive layer and the first upper insulating layer expose the first upper connection electrode, the adhesive layer and the first upper insulating layer may each have a curved corner.

In the display device according to embodiments of the present specification, in an area in which the second upper insulating layer exposes the first upper connection electrode, a corner of the second upper insulating layer may be a right angle.

In the display device according to embodiments of the present specification, a radius of curvature of a corner of the first upper insulating layer may be greater than a radius of curvature of a corner of the adhesive layer.

In the display device according to embodiments of the present specification, the light-emitting element may include a first area in contact with the first element contact electrode, a second area in contact with the second element contact electrode, and a light-emitting area between the first area and the second area.

According to embodiments of the present specification, there is provided a display device including a substrate, a driver adhesive layer on the substrate, a driving driver on the driver adhesive layer, a first protective layer on the driving driver, a second protective layer on the first protective layer, a first lower connection electrode disposed on the second protective layer and connected to a transistor through the first protective layer and the second protective layer, a second lower connection electrode disposed on the second protective layer and spaced apart from the first lower connection electrode, a lower insulating layer on the first lower connection electrode and the second lower connection electrode, a first upper connection electrode connected to the first lower connection electrode through the lower insulating layer on the lower insulating layer, a second upper connection electrode connected to the second lower connection electrode through the lower insulating layer on the lower insulating layer, an adhesive layer on the first upper connection electrode and the second upper connection electrode, a first element contact electrode on the adhesive layer, a light-emitting element on the first element contact electrode, a second element contact electrode on the light-emitting element, a third upper connection electrode connected to the second lower connection electrode and side surfaces of the first element contact electrode through the first adhesive layer, a first upper insulating layer on the adhesive layer and the third upper connection electrode, a second upper insulating layer on the first upper insulating layer, and a fourth upper connection electrode disposed on the second upper insulating layer and the second element contact electrode, connected to the first upper connection electrode through the second upper insulating layer, the first upper insulating layer, and the adhesive layer, and connected to the second element contact electrode, in which an end portion of the third upper connection electrode connected to side surfaces of the first element contact electrode is concave.

In the display device according to embodiments of the present specification, the third upper connection electrode may be spaced apart from the second element contact electrode.

In the display device according to embodiments of the present specification, the third upper connection electrode may surround the light-emitting element in a plan view.

In the display device according to embodiments of the present specification, the display device may further include an element insulating layer disposed on side surfaces of the light-emitting element, and the third upper connection electrode may be in direct contact with the element insulating layer.

In the display device according to embodiments of the present specification, the adhesive layer may include a second through hole exposing the first upper connection electrode, the first upper insulating layer may include a third through hole exposing the first upper connection electrode, the second upper insulating layer may include a fourth through hole exposing the first upper connection electrode, a width of the second through hole may be smaller than a width of the third through hole, and the width of the third through hole may be smaller than a width of the fourth through hole.

In the display device according to embodiments of the present specification, in an area in which the adhesive layer, the first upper insulating layer, and the second upper insulating layer expose the first upper connection electrode, the adhesive layer, the first upper insulating layer, and the second upper insulating layer may have a step structure.

In the display device according to embodiments of the present specification, in an area in which the adhesive layer and the first upper insulating layer expose the first upper connection electrode, the adhesive layer and the first upper insulating layer may each have a curved corner.

In the display device according to embodiments of the present specification, in an area in which the second upper insulating layer exposes the first upper connection electrode, a corner of the second upper insulating layer may be a right angle.

In the display device according to embodiments of the present specification, a radius of curvature of the corner of the first upper insulating layer may be greater than a radius of curvature of a corner of the adhesive layer.

In the display device according to embodiments of the present specification, the light-emitting element may include a first area in contact with the first element contact electrode, a second area in contact with the second element contact electrode, and a light-emitting area between the first area and the second area.

According to the embodiments of the present specification, stable connection between the light-emitting element and the electrodes can be achieved by forming side contact between the first element contact electrode and the third upper connection electrode.

According to the embodiments of the present specification, it is possible to simplify the process by electrically isolating the third upper connection electrode from the second element contact electrode by wet-etching the third upper connection electrode.

According to the embodiments of the present specification, it is possible to prevent disconnection of the fourth upper connection electrode by having a curvature at the corners of the adhesive layer and the first upper insulating layer during wet etching.

According to the embodiments of the present specification, the display device can be driven at low power.

However, effects obtainable from the present specification are not limited to the above effects, and other effects that are not described will be able to be clearly understood by those skilled in the art to which the present specification pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a transistor on the substrate;
a first protective layer on the transistor;
a second protective layer on the first protective layer;
a first lower connection electrode disposed on the second protective layer and connected to the transistor through the first protective layer and the second protective layer;
a second lower connection electrode disposed on the second protective layer and spaced apart from the first lower connection electrode;
a lower insulating layer on the first lower connection electrode and the second lower connection electrode;
a first upper connection electrode connected to the first lower connection electrode through the lower insulating layer;
a second upper connection electrode connected to the second lower connection electrode through the lower insulating layer;
an adhesive layer on the first upper connection electrode and the second upper connection electrode;
a first element contact electrode on the adhesive layer;
a light-emitting element on the first element contact electrode;
a second element contact electrode on the light-emitting element;
a third upper connection electrode connected to the second lower connection electrode through the adhesive layer and connected to side surfaces of the first element contact electrode;
a first upper insulating layer on the adhesive layer and the third upper connection electrode;
a second upper insulating layer on the first upper insulating layer; and
a fourth upper connection electrode disposed on the second upper insulating layer and the second element contact electrode, connected to the first upper connection electrode through the second upper insulating layer, the first upper insulating layer, and the adhesive layer, and connected to the second element contact electrode,
wherein an end of the first element contact electrode between the first upper insulating layer and the light-emitting element is concave.

2. The display device of claim 1, wherein the third upper connection electrode is spaced apart from the second element contact electrode.

3. The display device of claim 1, wherein the third upper connection electrode surrounds the light-emitting element in a plan view.

4. The display device of claim 1, further comprising an element insulating layer disposed on side surfaces of the light-emitting element, wherein the third upper connection electrode is in direct contact with the element insulating layer.

5. The display device of claim 1, wherein the adhesive layer includes a second through hole exposing exposes the first upper connection electrode, the first upper insulating layer includes a third through hole exposing the first upper connection electrode, the second upper insulating layer includes a fourth through hole exposing the first upper connection electrode, and a width of the second through hole is smaller than a width of the third through hole, and the width of the third through hole is smaller than a width of the fourth through hole.

6. The display device of claim 1, wherein, in an area in which the adhesive layer, the first upper insulating layer, and the second upper insulating layer expose the first upper connection electrode, the adhesive layer, the first upper insulating layer, and the second upper insulating layer have a step structure.

7. The display device of claim 1, wherein, in an area in which the adhesive layer and the first upper insulating layer expose the first upper connection electrode, the adhesive layer and the first upper insulating layer each has a curved corner.

8. The display device of claim 7, wherein, in an area in which the second upper insulating layer exposes the first upper connection electrode, a corner of the second upper insulating layer is a right angle.

9. The display device of claim 7, wherein a radius of curvature of a corner of the first upper insulating layer is greater than a radius of curvature of a corner of the adhesive layer.

10. The display device of claim 1, wherein the light-emitting element includes a first area in contact with the first element contact electrode, a second area in contact with the second element contact electrode, and a light-emitting area between the first area and the second area.

11. A display device comprising:
a substrate including a transistor;
a driver adhesive layer on the substrate;
a driving driver on the driver adhesive layer;
a first protective layer on the driving driver;
a second protective layer on the first protective layer;
a first lower connection electrode disposed on the second protective layer and connected to the transistor through the first protective layer and the second protective layer;
a second lower connection electrode disposed on the second protective layer and spaced apart from the first lower connection electrode;
a lower insulating layer on the first lower connection electrode and the second lower connection electrode;
a first upper connection electrode connected to the first lower connection electrode through the lower insulating layer;
a second upper connection electrode connected to the second lower connection electrode through the lower insulating layer;
an adhesive layer on the first upper connection electrode and the second upper connection electrode;
a first element contact electrode on the adhesive layer;
a light-emitting element on the first element contact electrode;
a second element contact electrode on the light-emitting element;
a third upper connection electrode connected to the second lower connection electrode through the adhesive layer and connected to side surfaces of the first element contact electrode;
a first upper insulating layer on the adhesive layer and the third upper connection electrode;
a second upper insulating layer on the first upper insulating layer; and
a fourth upper connection electrode disposed on the second upper insulating layer and the second element contact electrode, connected to the first upper connection electrode through the second upper insulating layer, the first upper insulating layer, and the adhesive layer, and connected to the second element contact electrode,
wherein an end portion of the third upper connection electrode connected to the side surfaces of the first element contact electrode is concave.

12. The display device of claim 11, wherein the third upper connection electrode is spaced apart from the second element contact electrode.

13. The display device of claim 11, wherein the third upper connection electrode surrounds the light-emitting element in a plan view.

14. The display device of claim 11, further comprising an element insulating layer disposed on side surfaces of the light-emitting element, wherein the third upper connection electrode is in direct contact with the element insulating layer.

15. The display device of claim 11, wherein the adhesive layer includes a second through hole exposing the first upper connection electrode, the first upper insulating layer includes a third through hole exposing the first upper connection electrode, the second upper insulating layer includes a fourth through hole exposing the first upper connection electrode, and a width of the second through hole is smaller than a width of the third through hole, and the width of the third through hole is smaller than a width of the fourth through hole.

16. A display device comprising:
a substrate including a transistor;
a first lower connection electrode electrically connected to the transistor;
a second lower connection electrode spaced from the first lower connection electrode;
a first insulating layer on the substrate;
an adhesive layer on the first insulating layer;
a light emitting element on the adhesive layer, the light emitting element including at least one element contact electrode;
a first upper connection electrode electrically connected to the first lower connection electrode; and
a second upper connection electrode electrically connected to the second lower connection electrode;
a second insulating layer on the adhesive layer; and
a third upper connection electrode extending through the adhesive layer to electrically connect to the second upper connection electrode and extending through the second insulating layer to electrically connect to a side surface of the at least one element contact electrode,
wherein an end portion of the third upper connection electrode adjacent to the side surface of the at least one element contact electrode has an inwardly recessed shape.

17. The display device of claim 16, wherein the at least one element contact electrode includes a first element contact electrode and a second element contact electrode on the light emitting element, and
wherein the third upper connection electrode laterally contacts the side surface of the first element contact electrode.

18. The display device of claim 16, further comprising a through-hole in the adhesive layer, wherein the third upper connection electrode extends through the through-hole in the adhesive layer to contact the second upper connection electrode.

19. The display device of claim 16, wherein the third upper connection electrode is disposed to surround the light emitting element in a plan view.

20. The display device of claim 16, further comprising a plurality of through-holes formed through the adhesive layer and the second insulating layer, wherein the plurality of through-holes have progressively increasing widths to form a step structure, wherein the display device further comprises a fourth upper connection electrode on the step structure and electrically connected to the light-emitting element, wherein at least one corner of the adhesive layer or the second insulating layer is rounded or curved in an area where the fourth upper connection electrode is disposed.
